(19) United States
(12) Patent Application Publication
(10) Pub. No.: US 2017/0365449 A1
(43) Pub. Date: Dec. 21, 2017

(54) RF RETURN STRAP SHIELDING COVER

(71) Applicant: Applied Materials, Inc., Santa Clara, CA (US)

(72) Inventors: Yi CUI, San Jose, CA (US); Robin L. TINER, Santa Cruz, CA (US); Beom Soo PARK, San Jose, CA (US); Soo Young CHOI, Fremont, CA (US); Shinichi KURITA, San Jose, CA (US)

(21) Appl. No.: 15/626,960

(22) Filed: Jun. 19, 2017

Related U.S. Application Data
(60) Provisional application No. 62/352,871, filed on Jun. 21, 2016.

(51) Int. Cl. H01J 37/32; C23C 16/505; C23C 16/458; H05K 9/00; H01L 21/687

(52) U.S. Cl. CPC H01J 37/32651; H05K 9/002; H01L 21/68785; H01J 37/32715; C23C 16/4586; H01J 37/32467; C23C 16/505; H01J 2237/3321

(57) ABSTRACT

Embodiments described herein generally relate to a substrate support assembly having a shield cover. In one embodiment, a substrate support assembly is disclosed herein. The substrate support assembly includes a support plate, a plurality of RF return straps, at least one shield cover, and a stem. The support plate is configured to support a substrate. The plurality of RF return straps are coupled to a bottom surface of the support plate. At least one shield cover is coupled to the bottom surface of the support plate, between the plurality of RF return straps and the bottom surface. The stem is coupled to the support plate.

### CROSS-REFERENCE TO RELATED APPLICATIONS

This application claims priority from U.S. Provisional Application Ser. No. 62/352,871, filed Jun. 21, 2016, which is hereby incorporated by reference in its entirety.

### BACKGROUND

### Field

Embodiments described herein generally relate to a substrate support assembly, and more specifically, to a substrate support assembly having at least one shield cover configured to prevent plasma arcing.

### Description of the Related Art

Flat panel displays (FPD) are commonly used for active matrix displays such as computer and television monitors, personal digital assistants (PDAs), and cell phones, as well as solar cells and the like. Plasma enhanced chemical vapor deposition (PECVD) may be employed in flat panel display fabrication to deposit thin film on a substrate supported within a vacuum processing chamber on a substrate support assembly. PECVD is generally accomplished by energizing a precursor gas into a plasma within the vacuum processing chamber, and depositing a film on the substrate from the energized precursor gas.

When the precursor gas in energized, an RF current return path is formed in the processing chamber. The RF current travels from the showerhead, through the substrate support assembly, down the RF current return straps to the chamber bottom, and back up to the chamber lid along the sidewalls of the processing chamber. As processing chambers increase in size, the path length of the RF current return path increases. The long length of the RF current return path results in a large voltage drop between the substrate support assembly and the sidewalls of the processing chamber. The large voltage drop may undesirably induce arching between the sidewall and the substrate support assembly.

Moreover, since the RF current return straps have generally looped shape, the RF current running through the strap can under certain conditions energize gases present below the substrate support assembly through inductive coupling to form a parasitic plasma. The parasitic plasma may promote unwanted deposition below the substrate support assembly which may later become a source of contamination and undesirably decrease the time between chamber cleans, and may also attack chamber components through plasma induced erosion and electrical arcing, thereby reducing their service life.

Thus, there is a need for an improved substrate support assembly.

### SUMMARY

Embodiments described herein generally relate to a substrate support assembly having a shield cover. In one embodiment, a substrate support assembly includes a support plate, a plurality of RF return straps, at least one shield cover, and a stem. The support plate is configured to support a substrate and is coupled to the stem. The plurality of RF return straps are coupled to the support plate and extend below a bottom surface of the support plate. At least one shield cover is coupled to the support plate and covers at least a portion of a side of at least one of the plurality of RF return straps closest a perimeter of the support plate.

In another embodiment, a processing chamber is disclosed herein. The processing chamber includes a chamber body and a substrate support assembly. The chamber body includes a lid, a sidewall, and a bottom defining a processing region in the chamber body. The substrate support assembly is disposed on the processing region. The substrate support assembly includes a support plate, a plurality of RF return straps, at least one shield cover, and a stem. The support plate coupled to the support plate and is configured to support a substrate. The plurality of RF return straps are coupled to between the support plate and the bottom of the chamber body. At least one shield cover is coupled to the support plate. The least one shield cover is deposed between at least one of the plurality of RF return straps and the sidewall of the chamber body.

In another embodiment, a method of processing a substrate is disclosed herein. The method includes placing a substrate on a substrate support assembly disposed in a processing chamber. Generating a plasma within the processing chamber, wherein RF current utilized to generate the plasma travels through an RF return strap coupling the substrate support assembly and a body of the processing chamber. The substrate support assembly having a shield cover disposed between chamber body and a portion of the RF return strap. The method further includes depositing a layer of material on the substrate disposed on the substrate support assembly while the substrate is exposed to the plasma.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a cross-sectional view of a processing chamber, according to one embodiment.

FIG. 2 illustrates a bottom view of the substrate support assembly of FIG. 1, according to one embodiment.

FIG. 3 is partial cross-sectional view of the processing chamber with the shield cover illustrated in phantom to reveal an RF current return strap, according to one embodiment.

FIG. 4 is a partial cross-sectional side view of the processing chamber illustrating gas flow around the shield cover illustrated in FIG. 3, according to one embodiment.

For clarity, identical reference numerals have been used, where applicable, to designate identical elements that are common between figures. Additionally, elements of one embodiment may be advantageously adapted for utilization in other embodiments described herein.

### DETAILED DESCRIPTION

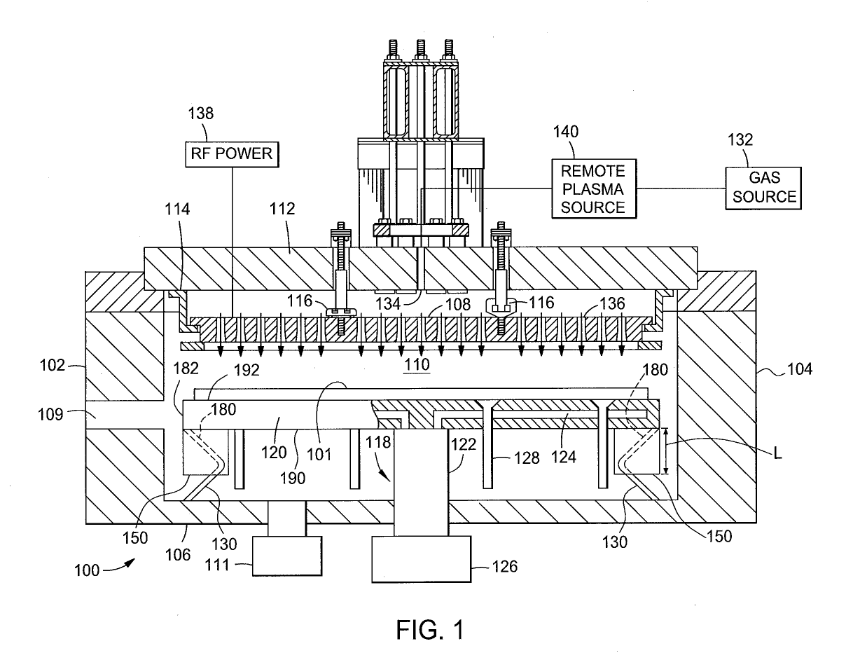

FIG. 1 illustrates a cross-sectional view of a processing chamber 100 having a substrate support assembly 118 with a shield cover 150, according to one embodiment. The shield cover 150 is utilized to reduce the probability of arcing within the processing chamber, and inhibit plasma formation below the substrate support assembly 118 within the processing chamber 100.

The processing chamber 100 includes a chamber body 102 having sidewalls 104, a bottom 106, and a showerhead 108 that define a processing volume 110. The processing volume 110 is accessed through a slit valve opening 109 formed through the sidewalls 104 to allow entry and egress of a substrate 101 that is processed within the processing volume 110 while disposed on the substrate support assembly 118.

The showerhead 108 is coupled to a backing plate 112. For example, the showerhead 108 may be coupled to the backing plate 112 by a suspension 114 at the periphery of the backing plate 112. One or more coupling supports 116 may be used to couple the showerhead 108 to the backing plate 112 to aid in controlling sag of the showerhead 108.

The substrate support assembly 118 is disposed in the processing volume 110 of the processing chamber 100. The substrate support assembly 118 includes a support plate 120 and a stem 122. The stem 122 is coupled to a bottom surface 190 of the support plate 120. An upper surface 192 of the support plate 120 is configured to support the substrate 101 during processing. The support plate 120 includes temperature control elements 124. The temperature control elements 124 are configured to maintain the substrate support assembly 118 at a desired temperature.

A lift system 126 may be coupled to the stem 122 to raise and lower the support plate 120. Lift pins 128 are moveably disposed through the support plate 120 to space the substrate 101 from the support plate 120 to facilitate robotic transfer of the substrate 101 though the slit valve opening 109.

The substrate support assembly 118 also includes at least one RF return strap 130. The RF return straps 130 are coupled between the support plate 120 and the chamber body 102. For example, one end of the RF return straps 130 may be coupled to the bottom surface 190 of the support plate 120 while the opposite end of the RF return straps 130 may be coupled to the bottom 106 of the chamber body 102. In one embodiment, the RF return straps 130 have a substantially vertical orientation. The RF return straps 130 provide an RF current path from the periphery of the substrate support assembly 118 to the bottom 106 of the chamber body 102.

The shield cover 150 is fabricated from a dielectric material. For example, the shield cover 150 may formed from ceramic or other suitable plasma resistant dielectric material. The shield cover 150 is coupled to the support plate 120 and covers at least a portion of at least one of the RF return straps 130 that is coupled to the support plate 120. The shield cover 150 covers at least a portion of an upper end 180 (shown in phantom in FIG. 1) of the RF return strap 130 that is attached to a perimeter 182 of the support plate 120. Thus, the position of the shield cover 150 disposed between the RF return strap 130 and the sidewall of the chamber body 102 substantially prevents arcing of the substrate support assembly and RF return strap 130 with the sidewalls of the chamber body 102.

In one example, the RF return strap 130 is coupled to the bottom surface 190 or perimeter 182 of the support plate 120. In another example, a plurality of shield covers 150 may be coupled to the support plate 120. For example, the plurality of shield covers 150 may be spaced about an outer edge of the bottom surface 190 (i.e., around the perimeter 182 of the support plate 120. In another embodiment, the plurality of shield covers 150 may be continuous about the outer edge of the bottom surface 190. The shield cover 150 may be positioned on the bottom surface 190 of the support plate 120 in a substantially horizontal orientation and extend below the bottom surface 190 of the support plate 120 to cover the upper end 180 of the RF return strap 130 that faces the sidewall of the chamber body 102. The shield cover 150 has a length, L, that the shield cover 150 extends below the support plate 120 that is short enough to accommodate the movement of the support plate 120 by the lift system 126 to a position that enable substrate transfer through the slit valve opening 109 without the shield cover 150 contacting the bottom 106 of the processing chamber 100. In yet another embodiment, the shield cover 150 may be coupled to a side of the support plate 120.

In one example, the shield cover 150 is in the form of a substantially flat plate. The shield cover 150, when fixed to the support plate 120, has a substantially vertical orientation that is parallel to the edge of the support plate 120 to which the shield cover 150 is attached. The shield cover 150 is to the support plate 120 in a manner that allows the shield cover 150 to extend below the bottom surface 190 of the support plate 120, thereby shielding the upper end 180 of the RF return strap 130.

Continuing to refer to the other components of the processing chamber 100, a gas source 132 may be coupled to the backing plate 112 to provide processing gas through a gas outlet 134 in the backing plate 112. The processing gas flows from the gas outlet 134 through gas passages 136 in the showerhead 108. A vacuum pump 111 may be coupled to the processing chamber 100 to control the pressure within the processing volume 110.

An RF power source 138 may be coupled to the backing plate 112 and/or to the showerhead 108 to provide RF power to the showerhead 108. The RF power creates an electric field between the showerhead 108 and the substrate support assembly 118 so that a plasma may be generated from the gases between the showerhead 108 and the substrate support assembly 118.

A remote plasma source 140, such as an inductively coupled remote plasma source, may also be coupled between the gas source 132 and the backing plate 112. Between processing substrates, a cleaning gas may be provided to the remote plasma source 140 so that a remote plasma is generated and provided into the processing volume 110 to clean chamber components. The cleaning gas may be further excited while in the processing volume 110 by power applied to the showerhead 108 from the RF power source 138. Suitable cleaning gases include but are not limited to NF₃, F₂, and SF₆.

The RF power from the RF power source 138 provided to the showerhead 108 and transferred across the plasma to the substrate support assembly 118, follows an RF return path from the substrate support assembly 118, to the bottom 106 of the processing chamber 100 through the RF return straps 130, and back up to the RF power source 138 via the sidewalls 104. Because the path of the RF return path is large, there is a large drop in voltage between the perimeter 182 of the support plate 120 (and RF return straps 130) and the sidewalls 104 of the chamber body 102. Under certain conditions, arcing may occur between the perimeter 182 of the support plate 120 (and RF return straps 130) and the sidewalls 104 of the chamber body 102 in processing chambers in which the shield cover 150 is not present. The dielectric insulation provided by the shield cover 150 between the perimeter 182 of the support plate 120 (and RF return straps 130) and the sidewalls 104 of the chamber body 102 substantially prevents arcing even though these components may have a high voltage drop along the RF return path. Additionally, the shield cover 150 inhibits gas flow directly between the upper end 180 of the shielded RF return straps 130 the perimeter 182 of the support plate 120 proximate the RF return straps 130. The inhibited gas flow further reduces the probability of undesirable plasma formation beneath the support plate 120 and proximate the RF return straps 130. Thus, presence of the shield cover 150 decreasing the chances of plasma arcing, and inhibits plasma formation below the support plate 120, which extends the mean time between chamber cleans and service life of the shielded RF return straps 130.

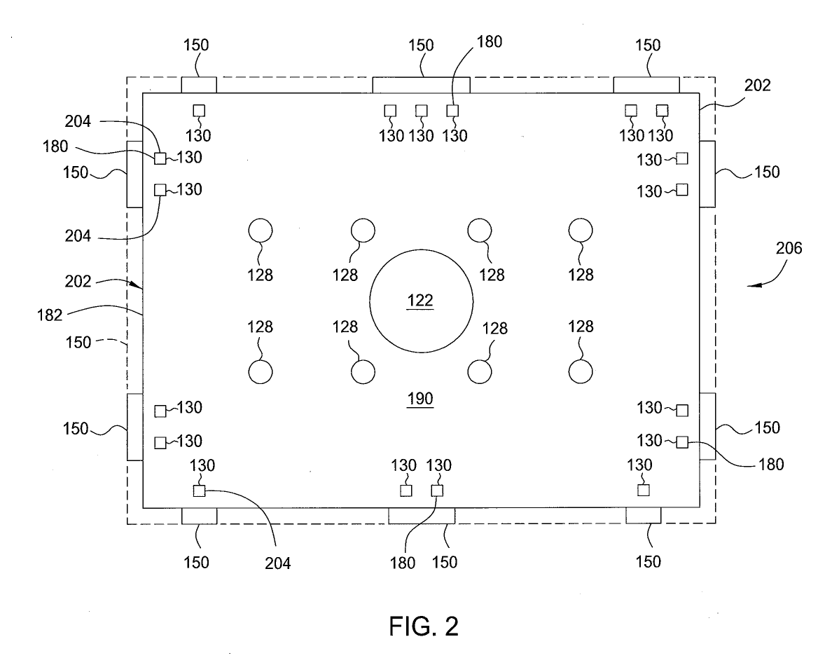

FIG. 2 illustrates a bottom view of the substrate support assembly 118 having at least one shield cover 150, according to one embodiment. As illustrated in FIG. 2, a plurality of shield covers 150 is coupled to the support plate 120. In one embodiment, the shield covers 150 may be coupled to an outer edge 202 of the support plate 120. For example, a single shield cover 150 may be coupled to the outer edge 202 of the support plate 120 such that the shield cover 150 covers at least a portion of a side 204 (i.e., the upper end 180) of at least two RF return straps 130 that are closest to the support plate 120. For example, a plurality of shield covers 150 may be coupled to the outer edge 202 of the support plate 120 such that the each shield cover 150 covers the side 204 and upper end 180 of a single RF return strap 130 in a one-to-one correspondence. Alternatively, each shield cover 150 may cover at least two RF return straps 130.

In another embodiment, the shield covers 150 (as shown in phantom) may be positioned along the outer edge 202 of the support plate 120 and circumscribe the entire perimeter 182 of the support plate 120. In another embodiment, the shield covers 150 may be positioned along one or more portions of the outer edge 202. For example, the shield covers 150 may be positioned along a short side 204 of the support plate 120, adjacent the slit valve opening 109 in the sidewalls 104, as the portion of the sidewalls 104 adjacent the slit valve opening 109 may have a high longer RF return path resulting in a larger voltage drop between the short side 204 of the support plate 120 and sidewalls 104 having the slit valve opening 109 formed therein.

The shield cover 150 is configured to shield the RF return straps 130 from the sidewall 104 of the chamber body 102 so that the sidewalls 104 and RF return straps 130 are not damaged from arcing. Thus, the shield cover 150 acts as an insulator between the sidewalls 104 and the RF return straps 130.

Thus, the shield cover 150 provides protection for the chamber sidewalls 104 from potential arcing due to the voltage drop between the substrate support assembly and the sidewalls of the processing chamber from the RF current loop.

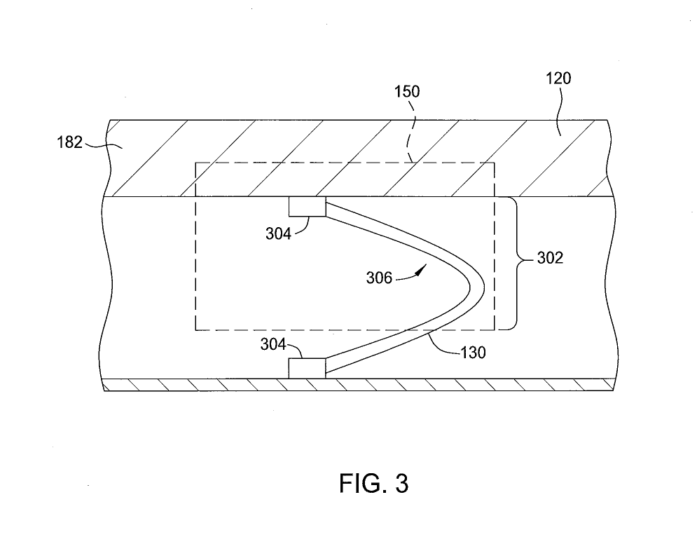

FIG. 3 is partial cross-sectional view of the processing chamber 100 illustrating the shield cover 150, according to one embodiment. The RF return strap 130 is coupled to the support plate 120 and the bottom 106 of the processing chamber 100 via clamps 304. The shield cover 150 is shown coupled to a side 182 of the support plate 120, such that at least an upper portion 306 of the RF return strap 130 is covered by the shield cover 150. The shield cover 150 is configured to block, or decrease, the amount of gas flowing (as depicted by flow arrows 402) beneath the support plate 120 in the vicinity, of the RF return strap 130, thereby forming a gas depleted area 302 immediately next to the upper portion 306 of the RF return strap 130. When RF current is provided to the support plate 120, the RF current runs through the support plate 120, down the RF return straps 130, along the bottom 106 of the chamber, up the sidewalls 104, and back to the RF power source 138. Because the upper portion 306 of the RF return straps 130 is in the gas depleted area 302, there is no gas to which the RF current running through the RF return straps 130 can inductively couple to, thereby reducing, if not eliminating, parasitic plasma below the support plate 120 in the vicinity of the upper portion 306 of the RF return strap 130. By creating the gas depleted area 302 beneath the support plate 120 and proximate the RF return strap 130, the shield cover 150 reduces the likelihood of parasitic plasma formation from inductive coupling beneath the support plate 120.

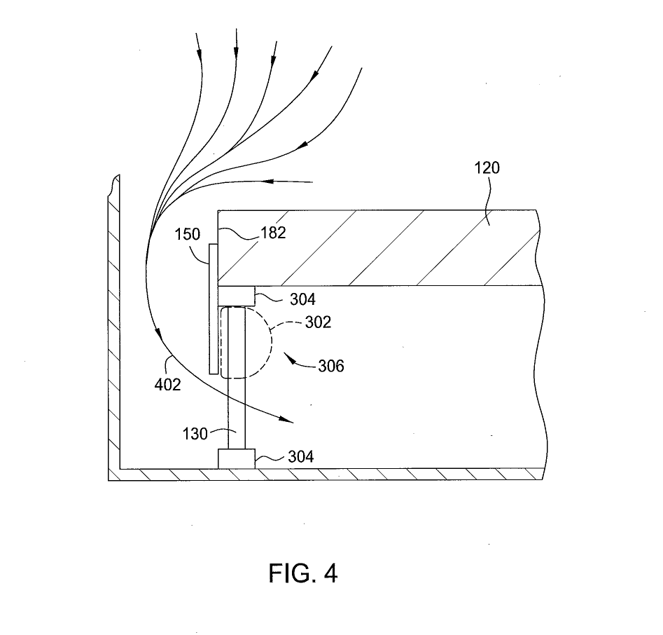

FIG. 4 is a partial cross-sectional side view of the processing chamber 100 illustrating the shield cover 150 in phantom to reveal the RF return strap 130, according to one embodiment. As discussed above, RF current travels up the sidewall 104 of the chamber 100 back to the RF power source 138 which may result in a substantial voltage potential between the upper portion 306 of the RF return strap 130 and the sidewall 104 of the processing chamber 100. The position of the shield cover 150 between the sidewall 104 and the RF return strap 130 inhibits the formation of parasitic plasma due to capacitive coupling between the sidewall 104 and the RF return strap 130. Moreover, the position of the shield cover 150 causes the gases within the processing chamber 100 to be shielded from the upper portion 306 of the RF return strap 130 as shown by gas flow arrows 402, thus forming the gas depleted area 302 immediately adjacent the upper portion 306 of the RF return strap 130. Because there is substantially less gas in the gas depleted area 302 as compared to conventional processing chambers, the likelihood of parasitic plasma formation from inductive coupling as current flows through the RF return strap 130. Moreover, as there is less gas in the gas depleted area 302, the potential for deposition on the underside of the support plate 120 is also substantially reduced, thereby advantageously reducing the probability of potential chamber contamination.

Thus, the shield cover 150 substantially reduces the potential for parasitic plasma formation beneath the support plate 120 and around the RF return strap 130, as well as reducing the potential for plasma arcing to the sidewalls 104 of the chamber 100

While the foregoing is directed to specific embodiments, other and further embodiments may be devised without departing from the basic scope thereof, and the scope thereof is determined by the claims that follow.

What is claimed is:

1. A substrate support assembly, comprising:
a support plate having an upper surface configured to support a substrate;
a stem coupled to a bottom surface of the support plate;
a plurality of RF return straps coupled to the support plate, the plurality of RF return straps extending below the bottom surface of the support plate;
at least one shield cover coupled to the support plate, wherein the at least one shield covers at least one a portion of a side of at least one of the plurality of RF return straps closest a perimeter of the support plate.

2. The substrate support assembly of claim 1, wherein the shield cover is a substantially flat plate having a substantially vertical orientation.

3. The substrate support assembly of claim 1, wherein the at least one shield cover further comprises:
a plurality of shield covers each coving at least one of the plurality of RF return straps.

4. The substrate support assembly of claim 3, wherein the shield covers are positioned on opposite sides of the support plate.

5. The substrate support assembly of claim 3, wherein the plurality of shield covers is continuous about an outer edge of the support plate.

6. The substrate support assembly of claim 1, wherein the shield cover is formed from a dielectric material.

7. The substrate support assembly of claim 1, wherein the at least one shield cover comprises: a single shield cover coving at least two of the RF return straps.

8. The substrate support assembly of claim 1, wherein the shield cover is positioned on a short side of the support plate.

9. A processing chamber, comprising:
a chamber body comprising a top wall, a sidewall, and a bottom wall defining a processing region in the chamber body; and
a substrate support assembly disposed in the processing region, the substrate support assembly, comprising:
a support plate having an upper surface configured to support a substrate;
a stem coupled to a bottom surface of the support plate;
a plurality of RF return straps coupled to the support plate, the plurality of RF return straps extending below the bottom surface of the support plate;
at least one shield cover coupled to the support plate, wherein the at least one shield covers at least one a portion of a side of at least one of the plurality of RF return straps closest a perimeter of the support plate.

10. The processing chamber of claim 9, wherein the shield cover is oriented horizontally and the RF return strap is oriented vertically.

11. The processing chamber of claim 9, further comprising:
a plurality of shield covers each coving at least one of the plurality of RF return straps.

12. The processing chamber of claim 11, wherein the shield covers a positioned on opposite sides of the support plate.

13. The processing chamber of claim 9, wherein the plurality of shield covers is continuous about an outer edge of the support plate.

14. The processing chamber of claim 9, wherein the shield cover is formed from a dielectric material.

15. The processing chamber of claim 9, wherein a single shield cover is positioned between the sidewall and at least two RF return straps.

16. The processing chamber of claim 9, wherein the shield cover is positioned on a short side of the support plate.

17. The processing chamber of claim 9, wherein the shield cover has a length such that when the substrate support assembly is in a lowered position, the shield cover does not contact the bottom wall of the processing chamber.

18. A method of processing a substrate, comprising:
generating a plasma within the processing chamber, wherein RF current utilized to generate the plasma travels through an RF return strap coupling the substrate support assembly and a body of the processing chamber, the substrate support assembly having a shield cover disposed between chamber body and a portion of the RF return strap; and
depositing a layer of material on the substrate disposed on the substrate support assembly while the substrate is exposed to the plasma.

19. The method of claim 18, wherein the shield cover is formed from a ceramic material.

20. The method of claim 18, wherein the shield cover is positioned on a bottom surface of the substrate support assembly between the body of the processing chamber and the RF return strap.
